(19) United States
(12) Patent Application Publication
(10) Pub. No.: US 2026/0155171 A1
(43) Pub. Date: Jun. 4, 2026

(54) COMPUTE IN MEMORY DEVICE, SYSTEM AND OPERATION METHOD THEREOF

(71) Applicant: National Yang Ming Chiao Tung University, Hsinchu City (TW)

(72) Inventors: Wei-Zen CHEN, Hsinchu County (TW); Yu-Chia CHEN, Taoyuan City (TW)

(21) Appl. No.: 19/090,349

(22) Filed: Mar. 25, 2025

(30) Foreign Application Priority Data
Nov. 29, 2024 (TW) 113146410

(51) Int. Cl. G11C 11/418; G11C 5/06; G11C 5/14

(52) U.S. Cl. CPC G11C 11/418; G11C 5/063; G11C 5/147

(57) ABSTRACT

The computing in memory device includes a memory circuit, a word line driver circuit, a detection circuit and a voltage modulation circuit. The memory circuit includes memory blocks arranged in parallel and coupled to each other through bit lines. Each memory block has memory cells respectively coupled to the bit lines. A word line and a power line couple the memory cells. The word line driving circuit generates an analog driving current according to the binary input value to drive the memory cells through the word line. The detection circuit detects this analog drive current. The voltage modulation circuit detects change of the output current based on the analog driving current to generate an operating voltage to provide to the memory cells through the power line.

### RELATED APPLICATIONS

This application claims priority to Taiwan Application Serial Number 113146410, filed Nov. 29, 2024, which are herein incorporated by reference.

### BACKGROUND

### Field of Invention

The present disclosure relates to a computer system. More particularly, the present disclosure relates to a computing in memory device, system and an operation method thereof.

### Description of Related Art

Traditionally, computing and storing are performed in different devices. Computing usually involves moving data from storage device to the processor for processing. In today's artificial intelligence and other related fields that require a lot of computing, this data movement process has become a bottleneck in the system's power consumption and speed performance.

Therefore, computing in memory technology has been developed to improve the above shortcomings to process large-scale data more effectively.

### SUMMARY

The foregoing presents a simplified summary of the disclosure in order to provide a basic understanding to the reader. This summary is not an extensive overview of the disclosure and it does not identify key/critical elements of the present disclosure or delineate the scope of the present disclosure. Its sole purpose is to present some concepts disclosed herein in a simplified form as a prelude to the more detailed description that is presented later.

One objective of the present disclosure is to provide a computing in memory which includes a memory circuit, a word line driving circuit, a detection circuit and a voltage modulation circuit. The memory circuit includes a plurality of memory blocks arranged in parallel and coupled to each other through a plurality of bit lines. Each of the plurality of memory blocks further includes a plurality of memory cells respectively coupled to the plurality of bit lines, a word line coupled to the plurality of memory cells for transmitting an analog driving current to the plurality of memory cells and a power line coupled to the plurality of memory cells to provide an operating voltage to the plurality of memory cells. The word line driving circuit generates the analog driving current according to a binary input value. The detection circuit detects the analog driving current. The voltage modulation circuit detects change of an output current based on the analog driving current, and generates the operating voltage based on the change of the output current.

In some embodiments, the word line driving circuit further includes a plurality of current sources, and the binary input value controls all or part of the plurality of current sources to generate the analog driving current.

In some embodiments, the detection circuit detects a driving current that the analog driving current distributes to each of the plurality of memory cells.

In some embodiments, the voltage modulation circuit detects change of the output current of a corresponding bit line according to the driving current, and generates the operating voltage according to the change of the output current.

In some embodiments, the voltage modulation circuit further includes: a redundant memory unit coupled to the corresponding bit line and an operating voltage generating circuit. The driving current drives the redundant memory unit, The operating voltage generating circuit detects change of the output current of the corresponding bit line to generate the operating voltage that compensates change of the output current.

In some embodiments, the voltage modulation circuit further includes a current mirror circuit for copying the driving current distributed to each of the plurality of memory cells to drive the redundant memory cell.

In some embodiments, the voltage modulation circuit generates a maximum operating voltage based on the analog driving current generated by all of the plurality of current sources, and determines an operating voltage range based on the operating voltage.

In some embodiments, each of the plurality of memory cells stores a binary weight value respectively.

In some embodiments, each of the plurality of memory cells is an 8T static random access memory, a 6T static random access memory, or a resistive memory.

One embodiment of the present invention provides a computing in memory system including a plurality of computing in memory devices. The corresponding bit lines of the plurality of computing in memory devices are coupled to each other to form a parallel architecture. The computing in memory devices generate different analog driving currents to drive corresponding memory circuits under same binary input value.

One embodiment of the present invention provides an operating method of a computing in memory device. The computing in memory device includes a memory circuit, and the memory circuit includes a plurality of memory blocks arranged in parallel and coupled to each other through a plurality of bit lines. Each of the plurality of memory blocks includes a plurality of memory cells respectively coupled to the plurality of bit lines. A word line is coupled to the plurality of memory cells unit. A power line coupled to the plurality of memory cells. The operation method includes receiving a binary input value to generate an analog driving current, wherein the analog driving current drives the plurality of memory cells through the word line, detecting change of the output current of the plurality of memory cells on the plurality of bit lines based on the analog driving current, and generating an operating voltage based on change of the output current, wherein the operating voltage is provided to the plurality of memory cells through the power line.

In some embodiments, the operating method of the computing in memory further includes controlling all or part of a plurality of current sources to generate the analog driving current in response to the binary input value.

In some embodiments, the operating method of the computing in memory further includes further includes generating the operating voltage in response to change of the output current.

In some embodiments, the operating method of the computing in memory further includes further includes using the driving current to drive a redundant memory unit, detecting the change of the output current of a bit line coupled to the redundant memory unit, and generating the operating voltage in response to the change of the output current.

In this application, a detection circuit can detect change of the output current of the memory circuit, and the voltage modulation circuit generates an operating voltage according to change of the output current to compensate for change of the output current to overcome the influence of environmental variability of large-scale computing unit. Moreover, the word line driving circuit adjusts the analog driving current of the memory circuit according to a binary input value, thereby achieving the purpose of multi-bit input and multi-bit weight and vector multiplication.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a schematic diagram of a computing in memory device according to an embodiment of the present invention.

FIG. 2 illustrates a schematic diagram of a digital to analog conversion circuit in the word line driving circuit according to an embodiment of the present invention.

FIG. 3 illustrates a schematic diagram of a voltage modulation circuit according to an embodiment of the present invention.

FIG. 4 illustrates a schematic diagram of a computing in memory system according to an embodiment of the present invention.

FIG. 5 illustrates a flow chart of an operating method of the computing in memory system according to an embodiment of the present invention.

### DESCRIPTION OF THE EMBODIMENTS

To make the contents of the present disclosure more thorough and complete, the following illustrative description is given with regard to the implementation aspects and embodiments of the present disclosure, which is not intended to limit the scope of the present disclosure. The features of the embodiments and the steps of the method and their sequences that constitute and implement the embodiments are described. However, other embodiments may be used to achieve the same or equivalent functions and step sequences.

Unless otherwise defined herein, scientific and technical terminologies employed in the present disclosure shall have the meanings that are commonly understood and used by one of ordinary skill in the art. Unless otherwise required by context, it will be understood that singular terms shall include plural forms of the same and plural terms shall include the singular. Specifically, as used herein and in the claims, the singular forms “a” and “an” include the plural reference unless the context clearly indicates otherwise.

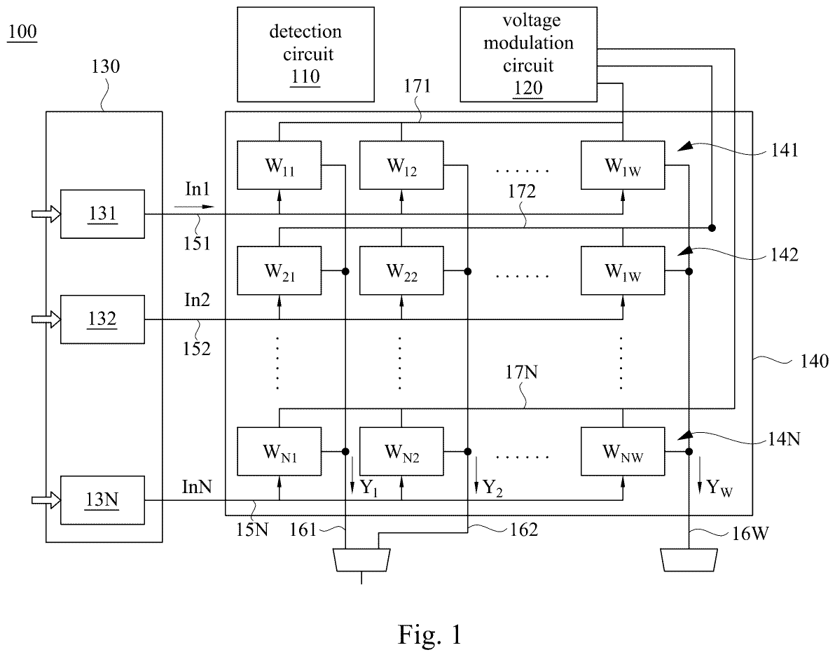

FIG. 1 illustrates a schematic diagram of a computing in memory device according to an embodiment of the present invention. The computing in memory device 100 includes a detection circuit 110, a voltage modulation circuit 120, a word line driving circuit 130 and a memory circuit 140.

In some embodiments, the memory circuit 140 is composed of an N*W memory array formed by a plurality of memory cells W₁₁, W₁₂, W₁₃ . . . . W_{NW}. The N*W memory array form a binary weight matrix. Each binary weight in the binary weight matrix is stored in a corresponding memory cells W₁₁, W₁₂, W₁₃ . . . . W_{NW} in the memory circuit 140. The memory circuit 140 includes a plurality of memory blocks 141, 142 . . . 14N arranged in parallel and coupled together through bit lines 161, 162, . . . , 16W. The memory cells W₁₁, W₁₂, W₁₃ . . . . W_{1W} in the first row in the memory circuit 140 form a memory block 141. The memory cells W₁₁, W₁₂, W₁₃ . . . . W_{1W} receive the operating voltage VDD from the power line 171 to generate computing in memory results of multiplication of the analog drive current on the word line 151 and weights stored in the memory cells W₁₁, W₁₂, W₁₃ . . . . W_{1W} on the bit lines 161, 162, . . . , 16W. The memory cells W₂₁, W₂₂, W₂₃ . . . . W_{2W} in the second row in the memory circuit 140 form a memory block 142. The memory cells W₂₁, W₂₂, W₂₃ . . . . W_{2W} receive the operating voltage VDD from the power line 172 to generate computing in memory results of multiplication of the analog drive current on the word line 152 and weights stored in the memory cells W₂₁, W₂₂, W₂₃ . . . . W_{2W} on the bit lines 161, 162, . . . , 16W. The operation of other memory blocks in the memory circuit 140 can be deduced in the same way. The computing in memory results of the memory cells in each memory block 141, 142 . . . 14N are added together to form a sum output from the bit lines 161, 162, . . . , 16W. Each of the memory cells W₁₁, W₁₂, W₁₃ . . . . W_{NW} can be a 8T static random-access memory (SRAM), a 6T static random-access memory or a resistive random-access memory (R-RAM). This present application is not limited to this.

In some embodiments, the word line driving circuit 130 includes a plurality of digital to analog conversion circuits 131, 132 . . . 13N. Each digital to analog conversion circuit 131, 132 . . . 13N determines an analog driving current based on a set of received binary values. These analog driving currents are applied to corresponding word lines 151, 152 . . . 15N to drive corresponding memory blocks 141, 142 . . . 14N to perform operation of computing in memory. For example, the digital to analog conversion circuit 131 can determine an analog driving current In1 based on the received first set of binary values, and apply this analog driving current In1 to the word line 151 to drive the memory cells, W₁₁, W₁₂, W₁₃ . . . . W_{1W}, in the memory block 141 to perform operation of computing in memory. The digital to analog conversion circuit 132 may determine an analog driving current In2 based on the received second set of binary values, and apply this analog driving current In2 to the word line 152 to drive the memory cells, W₂₁, W₂₂, W₂₃ . . . . W_{2W}, in the memory block 142 to perform operation of computing in memory. The digital to analog conversion circuit 13N may determine an analog driving current InN based on the received N-th set of binary values, and apply this analog driving current InN to the word line 15N to drive the memory cells, W_{N1}, W_{N2}, W_{N3} . . . . W_{NW}, in the memory block 14N to perform operation of computing in memory, and so on. After the word line driving circuit 130 applies corresponding analog driving currents, In1, In2 . . . . InN, to the word lines 151, 152 . . . 15N to drive the memory cells, W₁₁, W₁₂, W₁₃ . . . . W_{NW}, in the memory circuit 140, the memory circuit 140 performs operation of computing in memory to generate analog current values, Y₁, Y₂ . . . . Y_{W}, output from the bit lines 161, 162 . . . 16W. The analog current values, Y₁, Y₂ . . . . Y_{W}, represent the results of operations of computing in the memory circuit 140. In some embodiments, the analog current value Y₁ output from the bit line 161 is equal to (In1/W)*W₁₁+ (In2/W)*W₂₁+ . . . + (InN/W)*W_{N1}. The analog current value Y₂ output from the bit line 162 is equal to (In1/W)*W₁₂+ (In2/W)*W₂₂+ . . . + (InN/W)*W_{N2}. The analog current value Y_{W} output from bit line 16W is equal to (In1/W)*W_{1w}+(In2/W)*W_{2w}+ . . . +(InN/W)*W_{Nw}, and so on. In an embodiment, each analog current value, Y₁, Y₂ . . . . Y_{W}, can be converted into a binary value through a corresponding digital to analog conversion circuit.

In some embodiments, the detection circuit 110 is used to sense the analog driving current applied to each memory cell by the word line of each memory block 141, 142 . . . 14N. The detection circuit 110 detects changes of the output current on the bit line corresponds to each memory cell. In some embodiments, memory cells, W₁₁, W₁₂, W₁₃ . . . . W_{NW}, in the memory blocks 141, 142 . . . 14N receive the analog driving current provided on the word lines 151, 152, . . . , 15N to multiply with the weight values stored in the memory cells, W₁₁, W₁₂, W₁₃ . . . . W_{NW}, to form output currents output to the bit lines 161, 162, . . . , 16W respectively. However, the difference of locations of memory blocks 141, 142 . . . 14N may cause the output currents on the bit lines 161, 162, . . . , 16W be different even though these memory blocks 141, 142 . . . 14N are driven by a same analog driving current. Therefore, a detection circuit 110 in the present application is used to detect the difference of the output currents on the bit lines 161, 162, . . . , 16W to provide different operating voltages to the memory blocks 141, 142 . . . 14N. The different operating voltages are used to compensate the difference of the output currents on the bit lines 161, 162, . . . , 16W to ensure these output currents on the bit lines 161, 162, . . . , 16W are the same when a same analog driving current is used to drive these memory blocks 141, 142 . . . 14N. Accordingly, the voltage modulation circuit 120 may adjust the operating voltages dynamically to reduce the effects due to the differences of locations of memory blocks 141, 142 . . . 14N.

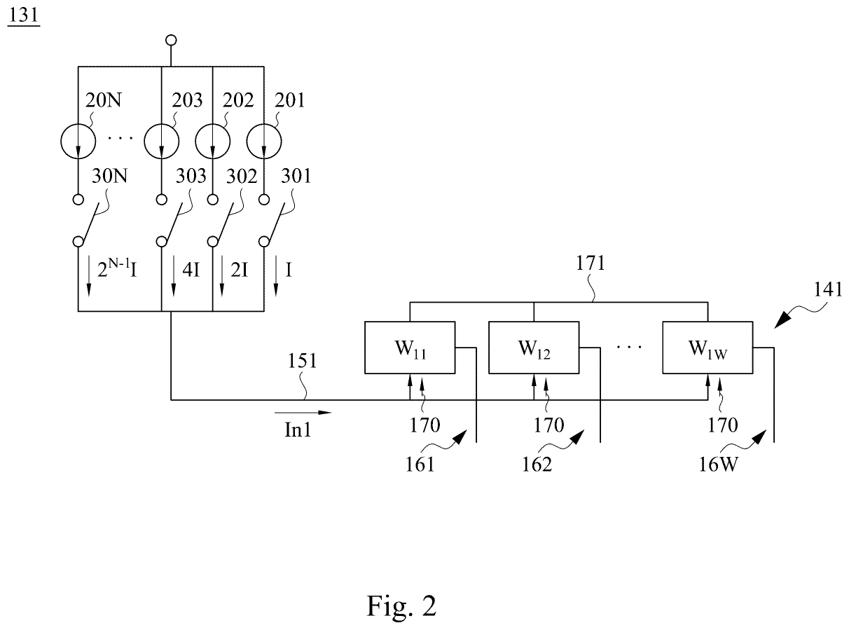

FIG. 2 illustrates a schematic diagram of a digital to analog conversion circuit in the word line driving circuit according to an embodiment of the present application. Each of the digital to analog conversion circuits 131, 132 . . . 13N in the word line driver circuit 130 has the same circuit structure. The following will take the digital to analog conversion circuit 131 as an example for explanation. The other digital to analog conversion circuits have the same circuit structure as the digital to analog conversion circuit 131. Please refer to FIGS. 1 and 2 at the same time. In some embodiments, the digital to analog conversion circuit 131 has current sources 201, 202, . . . , 20N arranged in parallel. The current sources 201, 202, . . . , 20N are coupled to the word line 151 through the switches 301, 302, . . . , 30N respectively. In some embodiments, the current sources 200, 201, . . . , 20N provide currents I, 2I, . . . 2^{N-1}I respectively. The switches 301, 302, . . . , 30N are switched according to a set of binary values received by the digital to analog conversion circuit 131 to determine the analog drive current applied to the word line 151. In some embodiments, the digital to analog conversion circuit 131 receives an N-bit binary value, and each bit controls the switching of the corresponding switches 301, 302, . . . , 30N. For example, the first bit of the N-bit binary value is used to control the switching of the switch 301, the second bit of the N-bit binary value controls the switching of the switch 302, the Nth bit of the N-bit binary value controls the switching of the switch 30N, and so on. In some embodiments, the binary value “1” is used to turn on the switch to provide the corresponding current to the word line 151, and the binary value “0” is used to turn off the switch to prohibit providing the corresponding current to the word line 151. In one implementation, if only the first bit of the N-bit binary value is “1” and the remaining bits of the N-bit binary value are “0”, the switch 301 is only switched on, and the current source 201 provides a current of I to the word line 151. In another embodiment, if the first bit and the second bit of the N-bit binary value are “1” and the remaining bits of the N-bit binary value are “0”, the switches 301 and 302 are switched, and the current source 201 and the current source 202 provide currents of I and 2I to the word line 151.

In some embodiments, the memory block 141 driven by the digital analog conversion circuit 131 includes W memory cells, W₁₁, W₁₂, W₁₃ . . . . W_{1W}, arranged in parallel. The analog driving current In1 on the word line 151 is used to drive the memory cells, W₁₁, W₁₂, W₁₃ . . . . W_{1W}, at the same time to perform operation of computing in memory. Therefore, the analog driving current provided to each memory cells, W₁₁, W₁₂, W₁₃ . . . . W_{1W}, will be 1/W times the analog driving current In1 on the word line 151. In some embodiments, if the analog driving current on the word line 151 is the current I provided by the current source 201, the analog driving current provided to each memory cells, W₁₁, W₁₂, W₁₃ . . . . W_{1W}, will be current I/W.

In some embodiments, the digital to analog conversion circuit 131 has four current sources 201, 202, 203, and 204 arranged in parallel. The four current sources 201, 202, 203, and 204 respectively provide currents of I, 2I, 4I, and 8I to the word line 151 through switches 301, 302, 303, and 304. The switches 301, 302, 303, and 304 are controlled by a 4-bit binary value received by the digital to analog conversion circuit 131. In some embodiments, if the 4-bit binary value is “0001”, the switch 301 is switched on, and the other switches 302, 303, and 304 are switched off. The analog driving current on the word line 151 is provided by the current source 201. Therefore, the current I is provided to the word line 151. The analog driving current provided to each memory cell, W₁₁, W₁₂, W₁₃ . . . . W_{1W}, in the memory block 141 will be I/W. In other embodiments, if the 4-bit binary value is “0011”, the switches 301 and 302 are switched on, the other switches are switched off. The analog driving current on the word line 151 is provided by the current source 201 and the current source 202. Therefore, the currents I and 2I are provided to the word line 151. The analog driving current provided to each memory cell, W₁₁, W₁₂, W₁₃ . . . . W_{1W}, in the memory block 141 will be 3I/W.

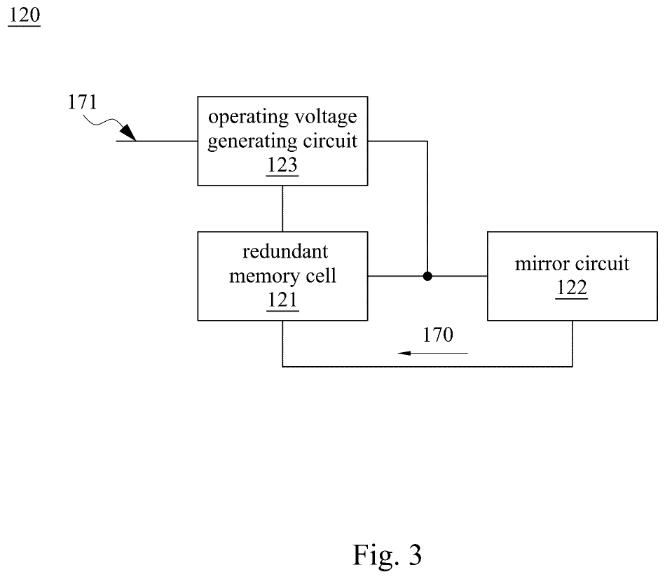

FIG. 3 illustrates a schematic diagram of a voltage modulation circuit according to an embodiment of the present invention. Please refer to FIGS. 1 to 3 at the same time. The voltage modulation circuit 120 is used to generate operating voltages VDD according to the analog driving currents provided to the memory cells, W₁₁, W₁₂, W₁₃ . . . . W_{NW}, in each memory block 141, 142 . . . 14N. The operating voltages VDD are provided to the power lines of memory cells, W₁₁, W₁₂, W₁₃ . . . . W_{NW}. By providing different operating voltages, the output currents of the memory blocks 141, 142 . . . 14N are compensated to reduce effects due to the differences of locations of memory blocks 141, 142 . . . 14N. The following will take the operating voltage VDD provided to the power line 171 for the memory cells, W₁₁, W₁₂, W₁₃ . . . . W_{1W}, in the memory block 141 as an example to illustrate the application of the present invention. The supply method of the operating voltage to the other memory blocks 142, 143, . . . 14N are similar to the memory block 141.

In some embodiments, the voltage modulation circuit 120 includes a redundant memory cell 121, a current mirror circuit 122 and an operating voltage generating circuit 123. The redundant memory cell 121 and the memory cells, W₁₁, W₁₂, W₁₃ . . . . W_{1W}, in the memory block 141 are manufactured at the same time. Therefore, the redundant memory cell 121 and the memory cells, W₁₁, W₁₂, W₁₃ . . . . W_{1W}, have the same features of effects of environmental variability. In some embodiments, the detection circuit 110 detects the current outputted by the current sources 201, 202, . . . , 20N in the digital to analog conversion circuit 131. The memory block 141 includes W memory cells, W₁₁, W₁₂, W₁₃ . . . . W_{1W}, arranged in parallel. Therefore, the detection circuit 110 can determine that the analog driving current 170 provided to each memory cell, W₁₁, W₁₂, W₁₃ . . . . W_{1W}, from the word line 151.

In some embodiments, the current mirror circuit 122 of the voltage modulation circuit 120 can mirror the analog driving current 170 to drive the redundant memory cell 121. The redundant memory cell 121 can generate an output current in the coupled bit line according to the analog driving current 170. The difference of location of redundant memory cell 121 may cause the output current in the coupled bit line be different even though the redundant memory cell 121 is driven by the same analog driving current 170. The operating voltage generating circuit 123 may generate an operating voltage VDD to compensate the effect caused by the difference of location of the redundant memory cell 121. Because the redundant memory cell 121 and the memory cells, W₁₁, W₁₂, W₁₃ . . . . W_{1W}, in the memory block 141 are manufactured at the same time, the operating voltage VDD generated by the operating voltage generating circuit 123 is synchronously provided to the power line 171 of the memory cells, W₁₁, W₁₂, W₁₃ . . . . W_{1W}, in the memory block 141. At this time, each of the memory cells, W₁₁, W₁₂, W₁₃ . . . . W_{1W}, in the memory block 141 will have the same operating state as the redundant memory cell 121. In other embodiments, the voltage modulation circuit 120 does not include a redundant memory cell 121. One of the memory cells, W₁₁, W₁₂, W₁₃ . . . . W_{1W}, of the memory block 141 is served as the redundant memory cell 121.

In some embodiments, the voltage modulation circuit 120 can further be used to determine the maximum operating voltage VDD provided to each memory block 141, 142 . . . 14N in the memory circuit 100. By providing different ranges of analog driving currents and corresponding operating voltages to different memory circuits 100, different memory circuits 100 may have different weights. In some embodiments, the detection circuit 110 detects the maximum analog driving current that can be output by the current sources 201, 202, . . . , 20N arranged in parallel in the digital to analog conversion circuit 131. In some embodiments, the current sources 201, 202, . . . , 20N provide analog driving currents of I, 2I, . . . 2^{N-1}I respectively. Therefore, the maximum analog driving current that the current sources 201, 202, . . . , 20N can provide is I+2I, . . . +2^{N-1}I. Because the memory block 141 includes memory cells, W₁₁, W₁₂, W₁₃ . . . . W_{1W}, arranged in parallel, the detection circuit 110 can determine the maximum analog driving current of each memory cells, W₁₁, W₁₂, W₁₃ . . . . W_{1W}, will be 1/W times of I+2I, . . . +2^{N-1}I. The current mirror circuit 122 in the voltage modulation circuit 120 can mirror the maximum analog driving current to drive the redundant memory unit 121. The operating voltage generating circuit 123 can adjust the generated operating voltage according to the maximum analog driving current to determine the maximum operating voltage of the memory circuit 100. The maximum operating voltage is used to set an operating voltage range. Accordingly, by setting different current sources in different memory circuits, and setting an operating voltage range according to the set current sources through the voltage modulation circuit, computing in memory devices with different weights may be provided.

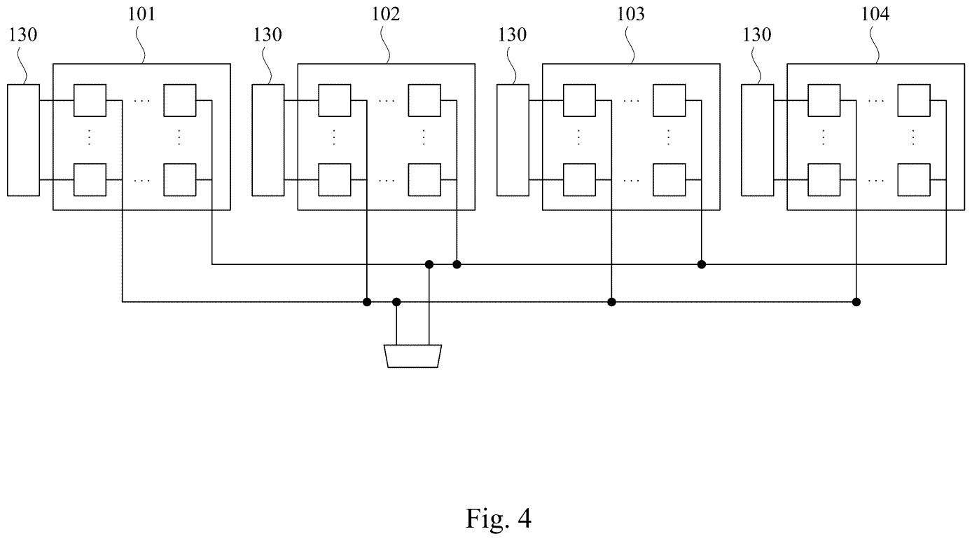

In some embodiments, different weighted output current combination may be realized by setting different current sources in different computing in memory devices 100 and connecting corresponding bit lines of the different computing in memory devices 100 in parallel. FIG. 4 shows a schematic diagram of connecting four computing in memory devices to form a computing in memory system according to a preferred embodiment of the present invention. It is worth noting that the number of computing in memory devices to form a computing in memory system is not limited to 4. In some embodiments, the computing in memory system includes a first computing in memory device 101, a second computing in memory device 102, a third computing in memory device 103 and a fourth computing in memory device 104. The structure of the first computing in memory device 101, the second computing in memory device 102, the third computing in memory device 103 and the fourth computing in memory device 104 is the same as that of the computing in memory device 100, only the current provided by the current source is different. In some embodiments, corresponding bit lines of the first computing in memory device 101, the second computing in memory device 102, the third computing in memory device 103 and the fourth computing in memory device 104 are coupled to each other in parallel. The minimum current I of the current source of the first computing in memory device 101 is 100 nA, the minimum current I of the current source of the second computing in memory device 102 is 200 nA, and the minimum current I of the current source of the third computing in memory device 103 is 400 nA, and the minimum current I of the current source of the fourth computing in memory device 104 is 800 nA. By setting different current sources, and setting an operating voltage range according to the set current sources through the voltage modulation circuit, the first computing in memory device 101, the second computing in memory device 102, and the third computing in memory device 103 and the fourth computing in memory device 104 have different weight. Therefore, when a same N-bit binary input value is inputted, different analog driving currents are generated to drive the first computing in memory device 101, the second computing in memory device 102, the third computing in memory device 103 and the fourth computing in memory device 104 to achieve the purpose of combining currents with different weights.

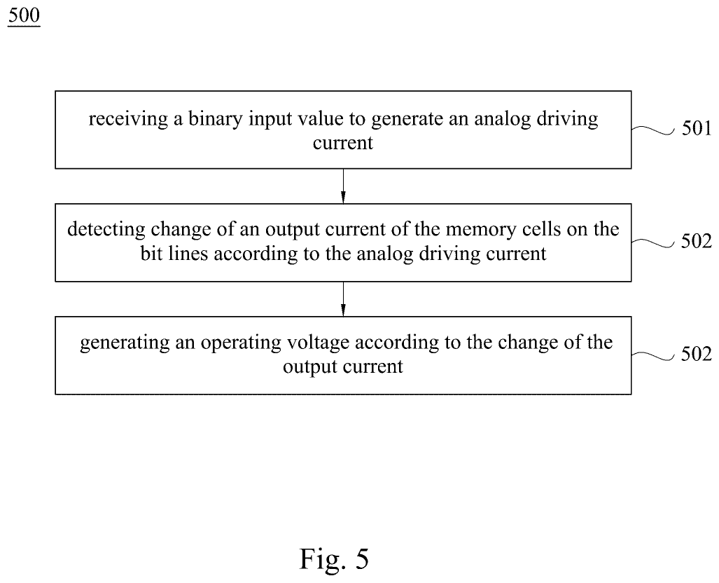

FIG. 5 shows a flow chart of an operating method of a computing in memory system according to a preferred embodiment of the present invention. The operating method 500 of a computing in memory system is used to operate the memory circuit 140 as shown in FIG. 1. First, in step 510, a binary input value is received to generate an analog driving current. The analog driving current is used to drive memory cells in a memory block through a word line. In some embodiments, as shown in FIG. 2, the digital to analog conversion circuit 131 has current sources 201, 202, . . . , 20N arranged in parallel. The current sources 201, 202, . . . , 20N are switched according to N-bit binary values to generate an analog driving current to drive memory cells in the memory block 141 through the word line 151.

In step 520, the changes of the output currents on the bit lines of the plurality of memory cells are detected according to the analog driving current. In some embodiments, the detection circuit 110 detects the analog driving currents generated by the current sources 201, 202, . . . , 20N arranged in parallel that output to drive the memory cells, W₁₁, W₁₂, W₁₃ . . . . W_{1W}, to determine the changes of the output currents on the bit lines 161, . . . 16W coupled to the memory cells, W₁₁, W₁₂, W₁₃ . . . . W_{1W}.

In step 530, an operating voltage is generated according to the changes of the output currents. The operating voltage is provided to the plurality of memory cells through the power line. In some embodiments, the operating voltage generating circuit 123 can generate an operating voltage VDD according to the change of the output current. The operating voltage VDD may be adjusted to compensate the change of the output current. The operating voltage VDD is provided to the memory cells, W₁₁, W₁₂, W₁₃ . . . . W_{1W}, in the memory block 141.

The above illustrations include sequential exemplary steps, but these steps need not be executed in the order shown It is within the scope of this disclosure to perform these steps in a different order. These steps may be added, substituted, changed in order and/or omitted as appropriate within the spirit and scope of the embodiments of the present disclosure.

Accordingly, computing in memory device, system and operating method of this present application includes a detection circuit and a voltage modulation circuit. The detection circuit can detect the change of the output current of the memory circuit. The voltage modulation circuit generates an operating voltage according to the change of the output current to compensate the change of the output current caused by the difference of location of the memory cells. Moreover, the word line driving circuit adjusts the analog driving current of the memory circuit according to a binary input value received by the word line driving circuit.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A computing in memory device, including:
a memory circuit, wherein the memory circuit includes a plurality of memory blocks arranged in parallel, and the plurality of memory blocks are coupled to each other through a plurality of bit lines, wherein each of the plurality of memory blocks further includes:
a plurality of memory cells respectively coupled to the plurality of bit lines;
a word line coupled to the plurality of memory cells for transmitting an analog driving current to the plurality of memory cells; and
a power line coupled to the plurality of memory cells for providing an operating voltage to the plurality of memory units;
a word line driving circuit for generating the analog driving current according to a binary input value;
a detection circuit for detecting the analog driving current; and
a voltage modulation circuit detects change of an output current based on the analog driving current to generate the operating voltage.

2. The computing in memory device of claim 1, wherein the word line driving circuit further includes a plurality of current sources, and the binary input value controls all or part of the plurality of current sources to generate the analog driving current.

3. The computing in memory device of claim 1, wherein the detection circuit further detect a drive current that the analog driving current distributes to each of the plurality of memory cells.

4. The computing in memory device of claim 3, wherein the voltage modulation circuit detects the change of the output current of a corresponding bit line according to the driving current to generate the operating voltage according to the change of the output current.

5. The computing in memory device of claim 4, wherein the voltage modulation circuit further includes:
a redundant memory cell coupled to the corresponding bit line and the driving current drives the redundant memory cell; and
an operating voltage generating circuit detects the change of the output current of the corresponding bit line to generate the operating voltage that compensates the change of the output current.

6. The computing in memory device of claim 5, wherein the voltage modulation circuit further includes a current mirror circuit for copying the driving current distributed to each of the plurality of memory cells to drive the redundant memory cell.

7. The computing in memory device of claim 2, wherein the voltage modulation circuit generates a maximum operating voltage based on the analog driving current generated by all of the plurality of current sources, and determines an operating voltage range based on the maximum operating voltage.

8. The computing in memory device of claim 1, wherein each of the plurality of memory cells stores a binary weight value.

9. The computing in memory device of claim 1, wherein each of the plurality of memory cells is an 8T static random access memory, a 6T static random access memory, or a resistive memory.

10. An computing in memory system, including:
a plurality of computing in memory devices as claimed in claim 1, wherein corresponding bit lines of the plurality of computing in memory devices are coupled to each other to form a parallel architecture, wherein the plurality of computing in memory devices generate different analog driving currents to drive corresponding memory circuits based on same binary input value.

11. An operating method of a computing in memory device, wherein the computing in memory device includes a memory circuit, and the memory circuit includes a plurality of memory blocks arranged in parallel and the memory blocks coupled to each other through a plurality of bit lines, wherein each of the plurality of memory blocks includes a plurality of memory cells respectively coupled to the plurality of bit lines, a word line coupled to the plurality of memory cells and a power line coupled to the plurality of memory cells, the operation method comprises:
receiving a binary input value to generate an analog driving current, wherein the analog driving current drives the plurality of memory cells through the word line;
detecting change of an output current of the plurality of memory cells on the plurality of bit lines based on the analog driving current; and
generating an operating voltage based on the change of the output current, wherein the operating voltage is provided to the plurality of memory cells through the power line.

12. The operating method of a computing in memory device of claim 11, further comprises controlling all or part of a plurality of current sources to generate the analog driving current in response to the binary input value.

13. The operating method of a computing in memory device of claim 11, further comprises generating the operating voltage in response to the change of the output current.

14. The operating method of a computing in memory device of claim 13, further comprises:
using the driving current to drive a redundant memory cell;
detecting the change of the output current of a bit line coupled to the redundant memory cell; and
generating the operating voltage in response to the change of the output current.

15. The operating method of a computing in memory device of claim 11, wherein each of the plurality of memory units is an 8T static random access memory, a 6T static random access memory or a resistive memory.
